(19) United States
(12) Patent Application Publication
(10) Pub. No.: US 2026/0247736 A1
(43) Pub. Date: Aug. 20, 2026

(54) IMAGE SENSOR WITH MULTIPLE CAPACITORS

(71) Applicant: SAMSUNG ELECTRONICS CO., LTD., Suwon-si (KR)

(72) Inventors: Hyunseung KIM, Suwon-si (KR); Keo-Sung PARK, Suwon-si (KR); Jungho PARK, Suwon-si (KR); Yeojin LEE, Suwon-si (KR); Seongho OH, Suwon-si (KR); Doyeon HA, Suwon-si (KR)

(73) Assignee: SAMSUNG ELECTRONICS CO., LTD., Suwon-si (KR)

(21) Appl. No.: 19/320,463

(22) Filed: Sep. 5, 2025

(30) Foreign Application Priority Data
Feb. 20, 2025 (KR) 10-2025-0022038

(51) Int. Cl. H10F 39/00; H10F 39/18; H10W 20/40

(52) U.S. Cl. CPC H10F 39/811; H10F 39/014; H10F 39/182; H10F 39/807; H10W 20/496

(57) ABSTRACT

An image sensor a substrate including a photodiode part; a first capacitor and a second capacitor spaced apart from each other on the substrate; a first via connected to the first capacitor; and a second via connected to the second capacitor, in which the first capacitor includes a first electrode, a second electrode, a third electrode and a first dielectric layer, in which the first dielectric layer is between the first electrode and the second electrode and between the second electrode and the third electrode, and in which the second capacitor comprises a fourth electrode, a fifth electrode, and a second dielectric layer, in which the second dielectric layer is between the fourth electrode and the fifth electrode.

### CROSS-REFERENCE TO RELATED APPLICATIONS

This U.S. non-provisional patent application claims priority under 35 U.S.C. §119 to Korean Patent Application No. 10-2025-0022038, filed on February 20, 2025, in the Korean Intellectual Property Office, the entire contents of which are hereby incorporated by reference.

### BACKGROUND

The present disclosure relates to an image sensor, and in particular, to an image sensor including a plurality of capacitors.

The image sensor is a semiconductor device converting an optical image to electric signals. The image sensor is classified into two types: a charge coupled device (CCD) type and a complementary metal-oxide-semiconductor (CMOS) type. In general, the CMOS-type image sensor may be called “CIS”. The CIS includes a plurality of pixels that are two-dimensionally arranged. Each of the pixels includes a photodiode (PD). The photodiode converts an incident light to an electric signal. However, for image sensors that are provided with a single capacitor with constant capacitance, there is a problem with a restriction on a degree of freedom for the arrangement and design of capacitors in which various capacitance values are required.

### SUMMARY

An embodiment of the present disclosure provides an image sensor with improved electrical characteristics.

According to an aspect of the disclosure, an image sensor, includes: a substrate comprising a photodiode part; a first capacitor and a second capacitor spaced apart from each other on the substrate; a first via connected to the first capacitor; and a second via connected to the second capacitor, in which the first capacitor comprises a first electrode, a second electrode, a third electrode and a first dielectric layer, in which the first dielectric layer is between the first electrode and the second electrode and between the second electrode and the third electrode, and in which the second capacitor comprises a fourth electrode, a fifth electrode, and a second dielectric layer, and in which the second dielectric layer is between the fourth electrode and the fifth electrode.

According to an aspect of the disclosure, an image sensor includes a substrate including a photodiode part, the substrate including a first surface and a second surface opposite to the first surface; a first capacitor and a second capacitor spaced apart from each other on the first surface of the substrate; a first via overlapping the first capacitor; a second via overlapping the second capacitor; and a third via between the first via and the second via, in which the first capacitor comprises a plurality of electrodes and a dielectric layer provided on at least one of electrode of the plurality of electrodes of the first capacitor, the second capacitor comprises a plurality of electrodes and a dielectric layer provided on at least one electrode of the plurality of electrodes of the second capacitor, the first via is connected to one or more electrodes of the plurality of electrodes of the first capacitor, the second via is connected to one or more electrodes of the plurality of electrodes of the second capacitor, the third via is connected to remaining electrodes of the plurality of electrodes of the first capacitor, excluding the one or more electrodes of the plurality of electrodes of the first capacitor connected to the first via, and a number of electrodes of the second capacitor is less than or equal to a number of electrodes of the first capacitor.

According to an aspect of the disclosure, an image sensor a substrate includes a plurality of photodiode parts, the substrate including a first surface and a second surface opposite to the first surface; an isolation structure in the substrate to separate at least two photodiode parts from the plurality of photodiode parts; a first capacitor and a second capacitor spaced apart from each other on the first surface of the substrate; a first via overlapping the first capacitor; and a second via overlapping the second capacitor, in which the first capacitor comprises a first electrode, a second electrode, a third electrode and a first dielectric layer, in which the first dielectric layer is between the first electrode and the second electrode and between the second electrode and the third electrode, in which the second capacitor comprises a fourth electrode, a fifth electrode and a second dielectric layer, in which the second dielectric layer is between the fourth electrode and the fifth electrode, and in which a capacitance value of the first capacitor is greater than a capacitor value of the second capacitor.

According to an embodiment of the present disclosure, a method of manufacturing an image sensor may include preparing a substrate, forming a photodiode parts in the substrate, and forming a first capacitor and a second capacitor spaced apart from each other on the substrate, wherein forming the first capacitor includes forming a first electrode, forming a second electrode on the first electrode, and forming a third electrode on the second electrode, and wherein forming the second capacitor includes forming a fourth electrode and forming a fifth electrode on the fourth electrode, and forming the second electrode and forming the fourth electrode may be performed simultaneously.

According to an embodiment of the present disclosure, forming the third electrode and forming the fifth electrode may be performed simultaneously.

According to an embodiment of the present disclosure, the method of manufacturing an image sensor may further comprise forming a first via connected to the first capacitor and forming a second via connected to the second capacitor, wherein the first via and the second via may be spaced apart from each other.

According to an embodiment of the present disclosure, forming the first to fifth electrodes may include being performed through a chemical vapor deposition process.

### BRIEF DESCRIPTION OF DRAWINGS

FIG. 1 is a plan view illustrating a light-receiving area in an image sensor according to some embodiments of the present disclosure.

FIG. 2 is a plan view illustrating a portion of a capacitor according to some embodiments of the present disclosure.

FIG. 3 is a plan view illustrating a portion of a capacitor according to some embodiments of the present disclosure.

FIG. 4 is a plan view illustrating a portion of a capacitor according to some embodiments of the present disclosure.

FIG. 5 is a cross-sectional view taken along line A-A’ of FIG. 1 according to some embodiments of the present disclosure.

FIG. 6 is a plan view illustrating a portion of a capacitor according to some embodiments of the present disclosure.

FIG. 7 is a plan view illustrating a portion of a capacitor according to some embodiments of the present disclosure.

FIG. 8 is a plan view illustrating a portion of a capacitor according to some embodiments of the present disclosure.

FIG. 9 is a cross-sectional view taken along line A-A’ of FIG. 1 according to some embodiments of the present disclosure.

FIG. 10 is a plan view illustrating an image sensor according to some embodiments of the present disclosure.

FIG. 11 is a cross-sectional view taken along line B-B’ of FIG. 10 according to some embodiments of the present disclosure.

FIG. 12 is a cross-sectional view taken along line B-B’ of FIG. 10 according to some embodiments of the present disclosure.

FIG. 13, 14, 15, 16 and 17 are cross-sectional views illustrating a process of fabricating an image sensor according to some embodiment of the present disclosure.

FIG. 18, 19, 20 and 21 are cross-sectional views illustrating a process of fabricating an image sensor according to some embodiment of the present disclosure.

### DETAILED DESCRIPTION

Example embodiments of the present disclosures will now be described more fully with reference to the accompanying drawings, in which example embodiments are shown.

It will be understood that, although the terms first, second, third, fourth, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the disclosure.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

A layer may be described as having an upper surface and a lower surface. As understood by one of ordinary skill in the art, the surfaces of a layer may also be described as first and second surfaces, where a first surface may be one of the upper surface and the lower surface of the layer, and the second surface may be the other of the upper surface and the lower surface of the layer.

The specification uses the terms of degree including “substantially” or “about.” In one or more examples, when specifying that a parameter X may be substantially the same as parameter Y, the term “substantially” may be understood as X being within 10% of Y. In one or more examples, when specifying that a parameter is about X, the term “about” may be understood as being within 10% of X.

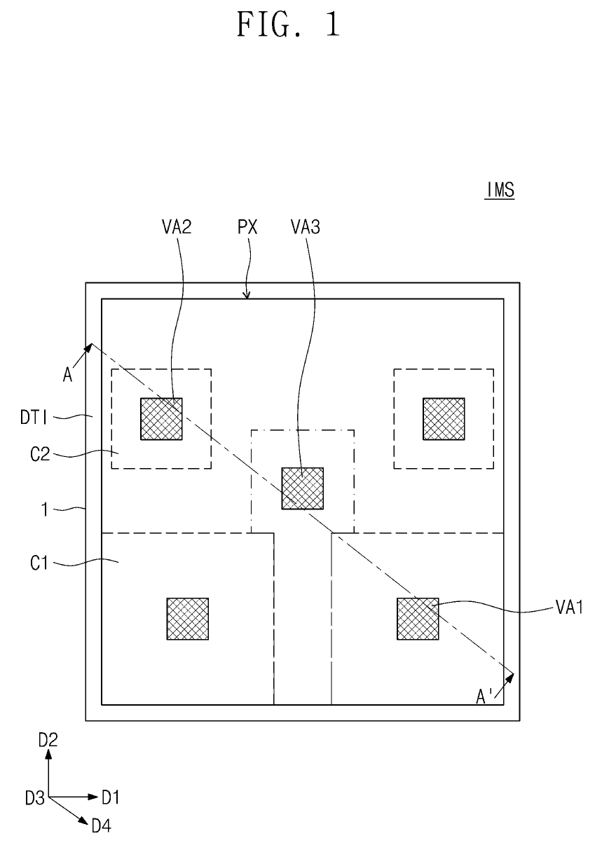

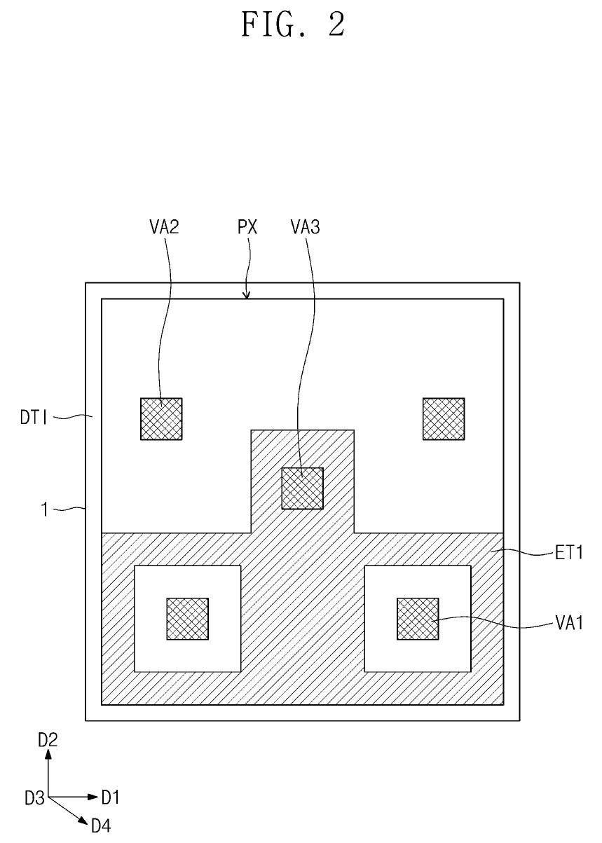

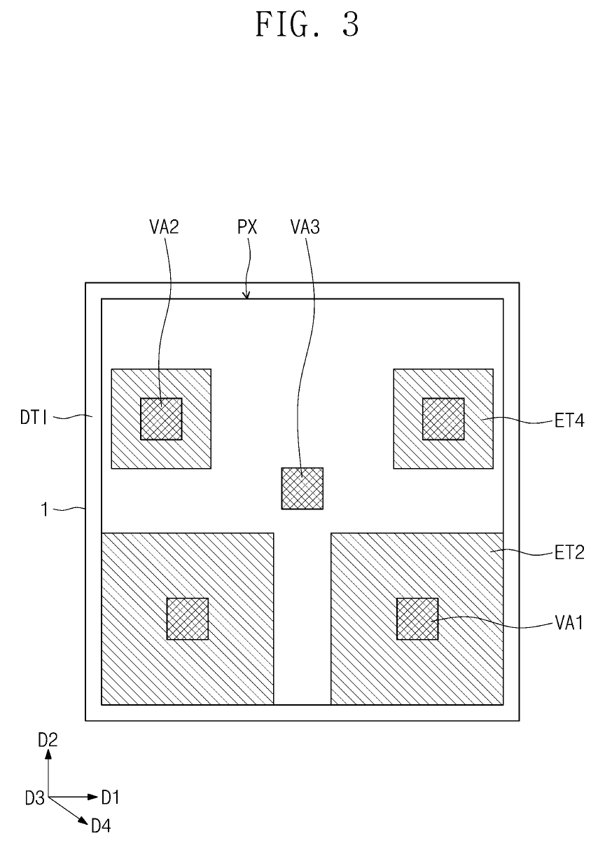

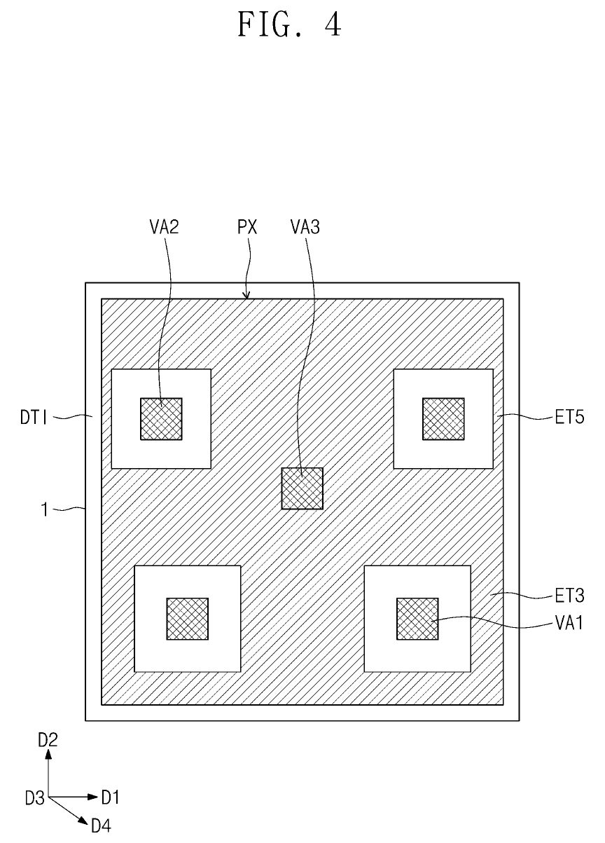

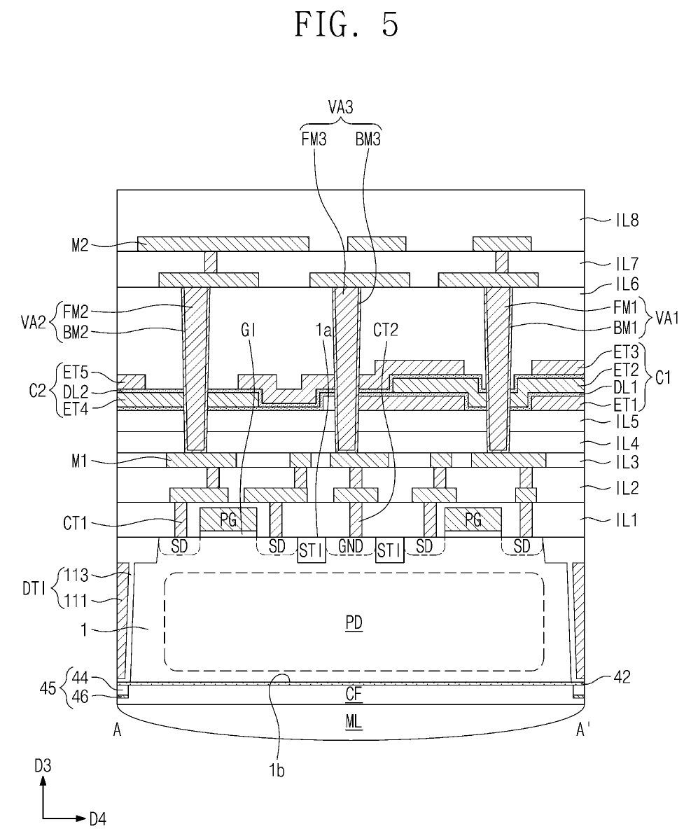

FIG. 1 is a plan view illustrating a light-receiving area in an image sensor according to some embodiments of the present disclosure. FIG. 2 is a plan view illustrating a portion of a capacitor according to some embodiments of the present disclosure. FIG. 3 is a plan view illustrating a portion of a capacitor according to some embodiments of the present disclosure. FIG. 4 is a plan view illustrating a portion of a capacitor according to some embodiments of the present disclosure. FIG. 5 is a cross-sectional view taken along line A-A’ of FIG. 1 according to some embodiments of the present disclosure.

Referring to FIGS. 1 to 5, an image sensor IMS according to some embodiments of the present disclosure may include a substrate 1. The substrate 1 may have a first surface 1a and a second surface 1b opposite to each other. Light may be incident into the substrate 1 through the second surface 1b. The substrate 1 may be a single crystal wafer containing silicon and/or germanium, epitaxial layer, or SOI (Silicon On Insulator) substrate. The substrate 1 may be doped with first dopants to have a first conductivity type. The first dopants may be, for example, boron. The first conductivity type may be, for example, P type.

In one or more examples, a first direction D1 may be defined as a direction parallel to the first surface 1a of the substrate 1. A second direction D2 may be defined as a direction parallel to the first surface 1a of the substrate 1 and perpendicular to the first direction D1. A third direction D3 may be defined as a direction perpendicular to the first surface 1a of the substrate 1. A fourth direction D4 may be defined as a direction that is parallel to the first surface 1a of the substrate 1 and crossing the first direction D1 and the second direction D2.

A photodiode part PD may be disposed in the substrate 1. A plurality of the photodiode parts PD may be provided in the image sensor IMS and may be separated from each other by an isolation structure DTI.

The photodiode part PD may be doped with one or more second dopants and have a second conductivity type different from the first conductivity type. The one or more second dopants may be, for example, phosphorus or arsenic. However, the embodiments of the present disclosure are not limited to these configurations or materials. The second conductivity type may be, for example, an n-type. In one or more examples, an n-type region of the photodiode part PD and the p-type region of the substrate 1 may form a p-n junction forming a photodiode, and if light is incident to the p-n junction, electron-hole pairs may be generated from the p-n junction. Electrons, which are generated through this process, may be transferred to the photodiode part PD. In this case, for example, electrons generated by the photodiode parts PD may be stored at a first capacitor C1.

Device isolation portions STI may be disposed in the substrate 1 to isolate components such as transistors. The device isolation portion STI may include at least one of silicon oxide, silicon nitride, and silicon oxynitride.

An isolation structure DTI separating the photodiode parts PD may be provided in the substrate 1. The isolation structure DTI may contact with the device isolation portions STI. The isolation structure DTI may penetrate the substrate 1. The isolation structure DTI may have a width in the first direction D1 that is tapered from the first surface 1a to the second surface 1b.

The isolation structure DTI may include a first isolation pattern 111 and a second isolation pattern 113. The first isolation pattern 111 may be spaced apart from the substrate 1. The first isolation pattern 111 may include a material having a refractive index different from that of the substrate 1. The first isolation pattern 111 may include, for example, polysilicon doped with dopants or metal.

The second isolation pattern 113 may be interposed between the first isolation pattern 111 and the substrate 1. The second isolation pattern 113 may include an insulating material having a refractive index different from that of the substrate 1. For example, the second isolation pattern 113 may include silicon oxide.

A negative bias voltage may be applied to the first isolation pattern 111. The first isolation pattern 111 may serve as a common bias line. In this case, it may be possible to immobilize holes, which may be present in a surface of the substrate 1 in contact with the isolation structure DTI, and thereby to improve a dark current property of the image sensor.

No boundary may be observed between the device isolation portion STI and the isolation structure DTI. For example, there may be no interface between the device isolation portion STI and the second isolation pattern 113.

A pixel transistor PG may be provided on a first surface 1a of a substrate 1. A gate insulating pattern GI may be interposed between the pixel transistor PG and the substrate 1.

The pixel transistor PG may include source/drain regions SD spaced apart from each other in the fourth direction D4. The pixel transistor PG may be, for example, one of a reset transistor, a source follower transistor, a dual conversion gain transistor, and a select transistor. The pixel transistor may be, for example, a sampling transistor.

A ground region GND may be provided in the substrate 1. The ground region GND may be provided, for example, between the device isolation portions STI.

A first to eighth interlayer insulating layers IL1 to IL8 may be provided on a first surface 1a of a substrate 1. The plurality of interlayer insulating layers IL1 to IL8 may include at least one of silicon oxide and silicon nitride. For example, the first to third interlayer insulating layers IL1 to IL3 may include silicon oxide. The fourth interlayer insulating layer IL4 may include silicon nitride. The fifth to eighth interlayer insulating layers IL5 to IL8 may include silicon oxide.

First contact plugs CT1 and second contact plugs CT2 may be provided to penetrate the first interlayer insulating layer IL1. The first contact plugs CT1 may be arranged spaced apart in the fourth direction D4 with the pixel transistor PG interposed therebetween. The first contact plugs CT1 may be connected to the source/drain regions SD. The second contact plugs CT2 may be connected to the ground region GND.

The first wiring patterns M1 may be provided in the first interlayer insulating layer to the fifth interlayer insulating layer IL1 to IL5. One or more of the plurality of the first wiring patterns M1 may be connected to the substrate 1 through the first contact plugs CT1 and the second contact plugs CT2.

A first capacitor C1 and a second capacitor C2 may be provided on the substrate 1 in the sixth interlayer insulating layer IL6. However, the embodiments are not limited to this configuration. For example, the first capacitor C1 and the second capacitor C2 may be provided in a higher or lower interlayer insulating layer. In one or more examples, the first capacitor C1 and the second capacitor C2 may be in different interlayer insulating layers. As shown in FIG. 1, the first capacitor C1 and the second capacitor C2 may be provided on one light-receiving area PX, for example. The first capacitor C1 and the second capacitor C2 may be arranged spaced apart from each other along the second direction D2 or the fourth direction D4. Hereinafter, for convenience of explanation, a single first capacitor C1 and a single second capacitor C2 will be described along the line A-A’ of FIG. 1. In one or more examples, the first capacitor C1 and the second capacitor C2 may be provided on different light-receiving areas.

The first capacitor C1 and the second capacitor C2 may overlap with the photodiode part PD in the third direction D3. The first capacitor C1 and the second capacitor C2 may each include a plurality of stacked electrodes and a dielectric layer provided on the electrodes. For example, each of the first capacitor C1 and the second capacitor C2 may be a MIM (Metal-Insulator-Metal) type capacitor. However, the embodiments are not limited to these configurations. For example, at least one of the first capacitor C1 and the second capacitor C2 may be a Metal-Oxide-Metal capacitor or a Metal-Oxide-Semiconductor (MOS) capacitor.

The number of electrodes included in each of the first capacitor C1 and the second capacitor C2 is not limited to the number shown in the drawings, and more electrodes may be provided. In one or more examples, a number of electrodes included in the second capacitor C2 may be less than or equal to a number of electrodes included in the first capacitor C1. Due to this example configuration, the capacitance value of the first capacitor C1 may be greater than the capacitance value of the second capacitor C2. However, as understood by one of ordinary skill in the art, the embodiments are not limited to this configuration. For example, the number of electrodes in the C2 may be greater than or equal to the number of electrodes included in the first capacitor C1

Specifically, referring to FIGS. 2 to 5, the first capacitor C1 may include a first electrode ET1, a second electrode ET2, and a third electrode ET3 provided on a substrate 1 and a first dielectric layer DL1 interposed between the first to third electrodes ET1-ET3, respectively. The second electrode ET2 and the third electrode ET3 may have a step structure. In one or more examples, the first dielectric layer DL1 may not be provided on the upper surface of the third electrode ET3 positioned at the top of the first capacitor C1.

The second capacitor C2 may include a fourth electrode ET4, a fifth electrode ET5 provided on the substrate 1, and a second dielectric layer DL2 interposed between the fourth electrode ET4 and the fifth electrode ET5. The fifth electrode ET5 may have a step structure. In one or more examples, the second dielectric layer DL2 may not be provided on the upper surface of the fifth electrode ET5 positioned at the top of the second capacitor C2.

Referring to FIGS. 2 to 4, from a planar perspective, the sum of the area of the third electrode ET3 and the area of the fifth electrode ET5 may be larger than the area of the first electrode ET1 and larger than the sum of the area of the second electrode ET2 and the area of the fourth electrode ET4.

The first electrode ET1, the second electrode ET2, the third electrode ET3, the fourth electrode ET4, and the fifth electrode ET5 may include, for example, at least one of doped polysilicon, aluminum (AI), copper (Cu), tungsten (W), ruthenium (Ru), rhodium (Rh), titanium (Ti), tantalum (Ta), titanium nitride (TiN), and tantalum nitride (TaN). The first dielectric layer DL1 and the second dielectric layer DL2 may include, for example, at least one of aluminum oxide (AlO), hafnium oxide (HfO), iridium oxide (IrO₂), and ruthenium oxide (RuO₂).

A first via VA1 may overlap with the first capacitor C1. The first via VA1 may be connected to the first capacitor C1. The first via VA1 may penetrate the first capacitor C1 and the fourth to sixth interlayer insulating layers IL4-IL6. The first via VA1 may be connected to one or more electrodes of the first capacitor C1. Specifically, the first via VA1 may penetrate the second electrode ET2 and be spaced apart from the first electrode ET1 and the third electrode ET3.

One end of the first via VA1 may be connected to the first wiring patterns M1. The other end of the first via VA1 may be connected to the second wiring patterns M2. The first via VA1 may be electrically connected to the source/drain region SD through the first wiring patterns M1 and the first contact plugs CT1. The first via VA1 may be a node selection via.

The first via VA1 may include a first conductive pattern FM1 and a first barrier pattern BM1 on the first conductive pattern FM1. The first barrier pattern BM1 may cover a lower surface and a side surface of the first conductive pattern FM1. For example, the first conductive pattern FM1 may include at least one metal of aluminum (AI), copper (Cu), tungsten (W), molybdenum (Mo), and cobalt (Co). The first barrier pattern BM1 may include a metal layer/metal nitride layer.

The second via VA2 may overlap with the second capacitor C2. The second via VA2 may connected to the second capacitor C2. The second via VA2 may be spaced apart from the first via VA1 in the second direction D2 and the fourth direction D4. A second via VA2 may penetrate the second capacitor C2 and the fourth to sixth interlayer insulating layers IL4-IL6. The second via VA2 may be connected to one or more electrodes of the second capacitor C2. Specifically, the second via VA2 may penetrate the fourth electrode ET4 and be spaced apart from the fifth electrode ET5.

One end of the second via VA2 may be connected to the first wiring patterns M1. The other end of the second via VA2 may be connected to the second wiring patterns M2. The second via VA2 may be electrically connected to the source/drain region SD through the first wiring patterns M1 and the first contact plug CT1. The second via VA2 may be a node selection via.

The second via VA2 may include a second conductive pattern FM2 and a second barrier pattern BM2 on the second conductive pattern FM2. The second barrier pattern BM2 may cover a lower surface and a side surface of the second conductive pattern FM2. For example, the second conductive pattern FM2 may include at least one metal of aluminum (AI), copper (Cu), tungsten (W), molybdenum (Mo), and cobalt (Co). The second barrier pattern BM2 may include a metal layer/metal nitride layer.

A third via VA3 may be provided between the first via VA1 and the second via VA2. The third via VA3 may be spaced from the first via VA1 and the second via VA2 in the fourth direction D4. The third via VA3 may penetrate the fourth to sixth interlayer insulating layers IL4-IL6.

The third via VA3 may be connected to one or more remaining electrodes of the first capacitor C1 excluding the electrodes connected to the first via VA1. In this regard, the third via VA3 is connected to one or more electrodes of the first capacitor C1 that are not connected to the first via VA1. The third via VA3 may be connected to one or more remaining electrodes of the second capacitor C2 excluding the electrodes connected to the second via VA2. In this regard, the third via VA3 is connected to one or more electrodes of the first capacitor C2 that are not connected to the second via VA2. Specifically, the third via VA3 may be connected to the first electrode ET1 and the third electrode ET3 of the first capacitor C1. The third via VA3 may be connected to the fifth electrode ET5 of the second capacitor C2. The third via VA3 may be spaced apart from the second electrode ET2 and the fourth electrode ET4.

One end of the third via VA3 may be connected to the first wiring patterns M1. The other end of the third via VA3 may be connected to the second wiring patterns M2. The third via VA3 may be electrically connected to the ground region GND through the first wiring patterns M1 and the second contact plugs CT2.

The third via VA3 may include a third conductive pattern FM3 and a third barrier pattern BM3 on the third conductive pattern FM3. The third barrier pattern BM3 may cover a lower surface and a side surface of the third conductive pattern FM3. For example, the third conductive pattern FM3 may include at least one metal of aluminum (AI), copper (Cu), tungsten (W), molybdenum (Mo), and cobalt (Co). The third barrier pattern BM3 may include a metal layer/metal nitride layer.

A seventh interlayer insulating layer IL7 and an eighth interlayer insulating layer IL8 may be provided on the sixth interlayer insulating layer IL6. The second wiring patterns M2 may be provided in the seventh interlayer insulating layer IL7 and the eighth interlayer insulating layer IL8. The second wiring patterns M2 may be connected to the first via VA1, the second via VA2, and the third via VA3.

A fixed charge layer 42 may be provided on the second surface 1b of the substrate 1. The fixed charge layer 42 may be formed of a metal oxide layer with an oxygen content being lower than its stoichiometric ratio, or a metal fluoride layer with a fluorine content ratio being lower than its stoichiometric ratio. Thus, the fixed charge layer 42 may have a negative fixed charge. The fixed charge layer 42 may be formed of metal oxide or metal fluoride of at least one of hafnium (Hf), zirconium (Zr), aluminum (Al), tantalum (Ta), titanium (Ti), yttrium (Y), and lanthanoid. However, the embodiments of the present disclosure are not limited to these materials. The hole accumulation may occur near the fixed charge layer 42. In this case, it may be possible to effectively suppress a dark current issue and a white spot issue. In one or more examples, a dark current may be a current that flows through a device even in the absence of light. In one or more examples, a white spot may refer to a white spot defect in an image sensor. In some example embodiments, the fixed charge layer 42 may be formed of or include at least one of aluminum oxide (AlO) or hafnium oxide (HfO). However, example embodiments are not limited thereto.

A grid 45 may be provided on the fixed charge layer 42. The grid 45 may overlap with the isolation structure DTI in some areas, but may not overlap with the isolation structure DTI in other areas considering the angle of incidence. The grid 45 may include a first material pattern 44 and a second material pattern 46. The first material pattern 44 may include a material that does not transmit light, for example, titanium. A side wall of the second material pattern 46 may be aligned with a side wall of the first material pattern 44. The first material pattern 44 and the second material pattern 46 may prevent crosstalk between adjacent light-receiving areas PX. The second material pattern 46 may include an organic material. The second material pattern 46 may include, as an example, a fluorinated polymer-based organic material. The second material pattern 46 may have, for example, a refractive index of about 1.3 or less.

A color filter CF may be provided on the fixed charge layer 42. The color filter CF may include a photoresist material to which a dye or a pigment is added. Although not illustrated, on a plurality of photodiode parts PD, a plurality of color filters CF may be arranged in a Bayer pattern, a 2x2 array of Tetra patterns, a 3x3 array of patterns, a 4x4 array of patterns, or any other suitable material known to one of ordinary skill in the art. A micro lens ML may be provided on the color filter CF.

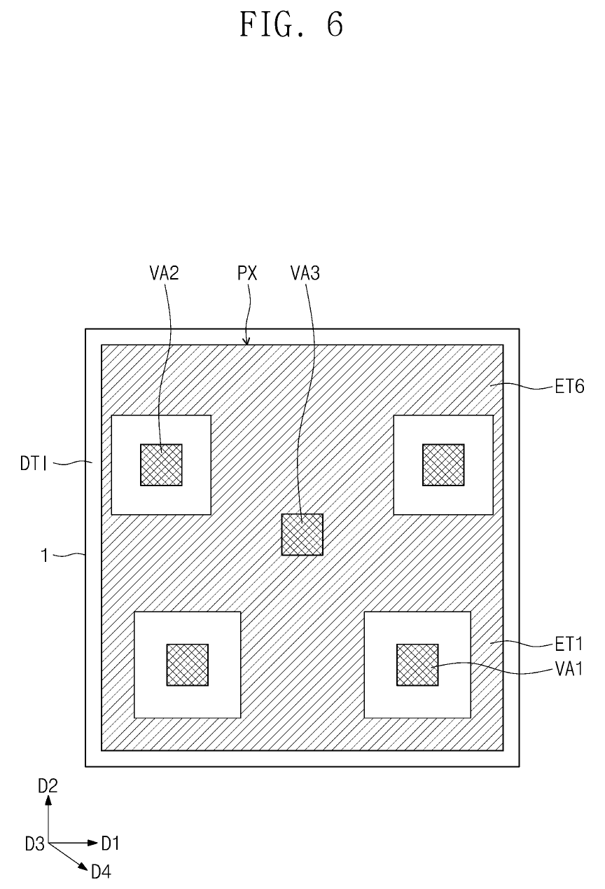

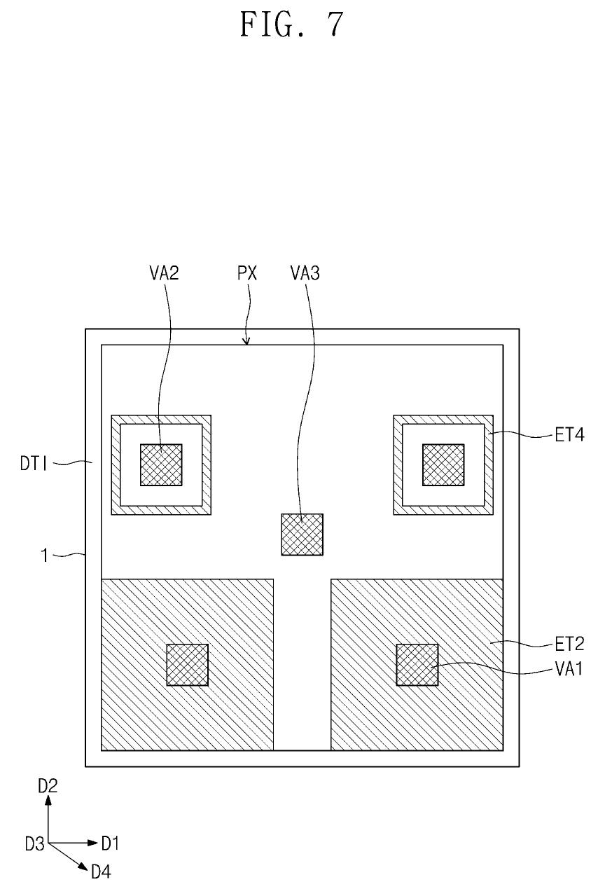

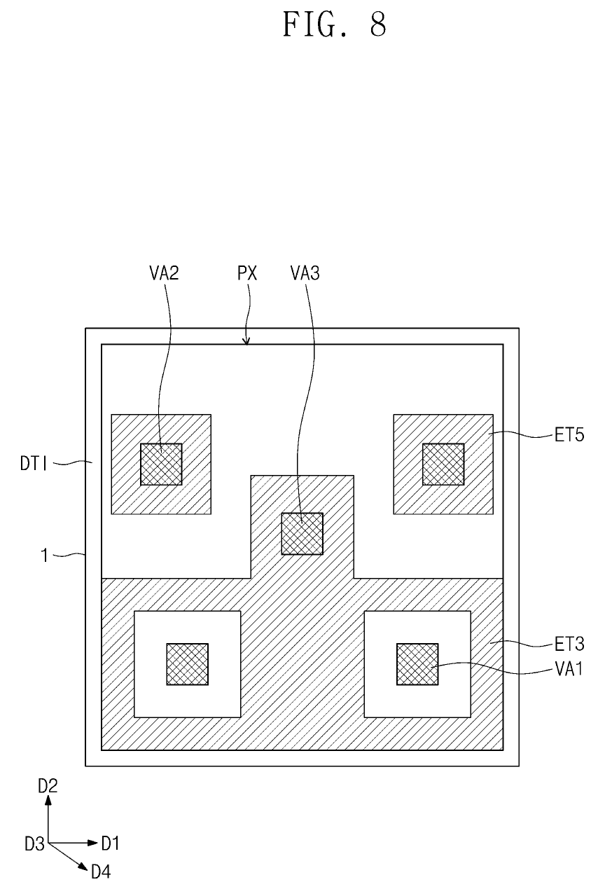

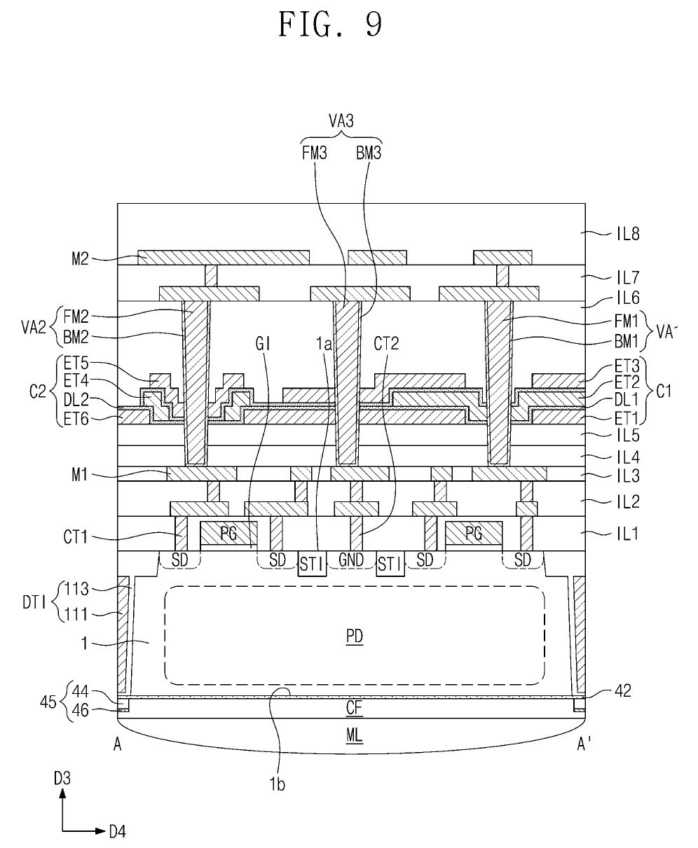

FIG. 6 is a plan view illustrating a portion of a capacitor according to some embodiments of the present disclosure. FIG. 7 is a plan view illustrating a portion of a capacitor according to some embodiments of the present disclosure. FIG. 8 is a plan view illustrating a portion of a capacitor according to some embodiments of the present disclosure. FIG. 9 is a cross-sectional view taken along line A-A’ of FIG. 1 according to some embodiments of the present disclosure.

Referring to FIGS. 6 to 9, the second capacitor C2 may further include a sixth electrode ET6 provided below the fourth electrode ET4. A level of the upper surface of the first electrode ET1 and a level of the upper surface of the sixth electrode ET6 may be substantially same. As shown in FIG. 6, the first electrode ET1 and the sixth electrode ET6 may form a single plate.

The fourth electrode ET4 is provided on side and upper surfaces of the sixth electrode ET6 and may have a step structure. For example, the fourth electrode ET4 may include a plurality of upper surfaces having different levels.

The level of the uppermost surface of the second electrode ET2 and the level of the uppermost surface of the fourth electrode ET4 may be substantially the same. The level of the uppermost surface of the third electrode ET3 and the level of the uppermost surface of the fifth electrode ET5 may be substantially the same.

The second via VA2 may penetrate through the fifth electrode ET5 and be spaced apart from the fourth electrode ET4 and the sixth electrode ET6.

The third via VA3 may be connected to the remaining electrodes of the first capacitor C1 excluding the electrode connected to the first via VA1. Specifically, the third via VA3 may be connected to the first electrode ET1 and the third electrode ET3 of the first capacitor C1. The third via VA3 may be connected to the sixth electrode ET6 of the second capacitor C2. The third via VA3 may be spaced from the second electrode ET2, the fourth electrode ET4, and the fifth electrode ET5.

In one or more examples, the fourth electrode ET4 included in the second capacitor C2 may be in a floating state and not electrically connected to the second via VA2 and the third via VA3. Therefore, a plurality of electrodes included in the second capacitor C2 may form an electrical series state. In one or more examples, the plurality of electrodes included in the first capacitor C1 may be electrically connected in parallel to the first via VA1 or the third via VA3, respectively. As a result, the capacitance value of the first capacitor C1 may be greater than that of the second capacitor C2.

Referring to FIGS. 6 to 8, from a planar perspective, the sum of the area of the first electrode ET1 and the area of the sixth electrode ET6 may be greater than the sum of the area of the second electrode ET2 and the area of the fourth electrode ET4. The sum of the area of the first electrode ET1 and the area of the sixth electrode ET6 may be greater than the sum of the area of the third electrode ET3 and the area of the fifth electrode ET5.

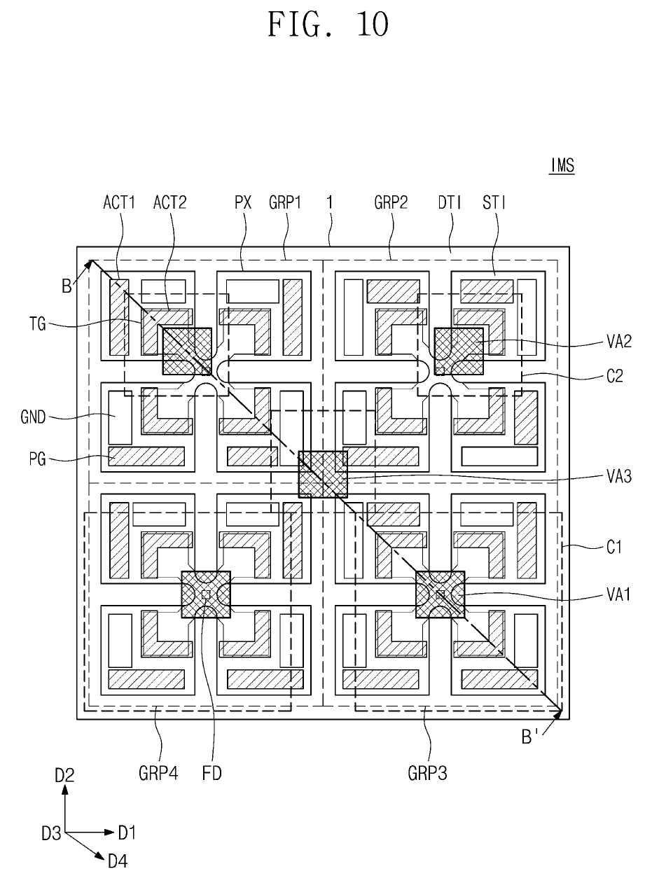

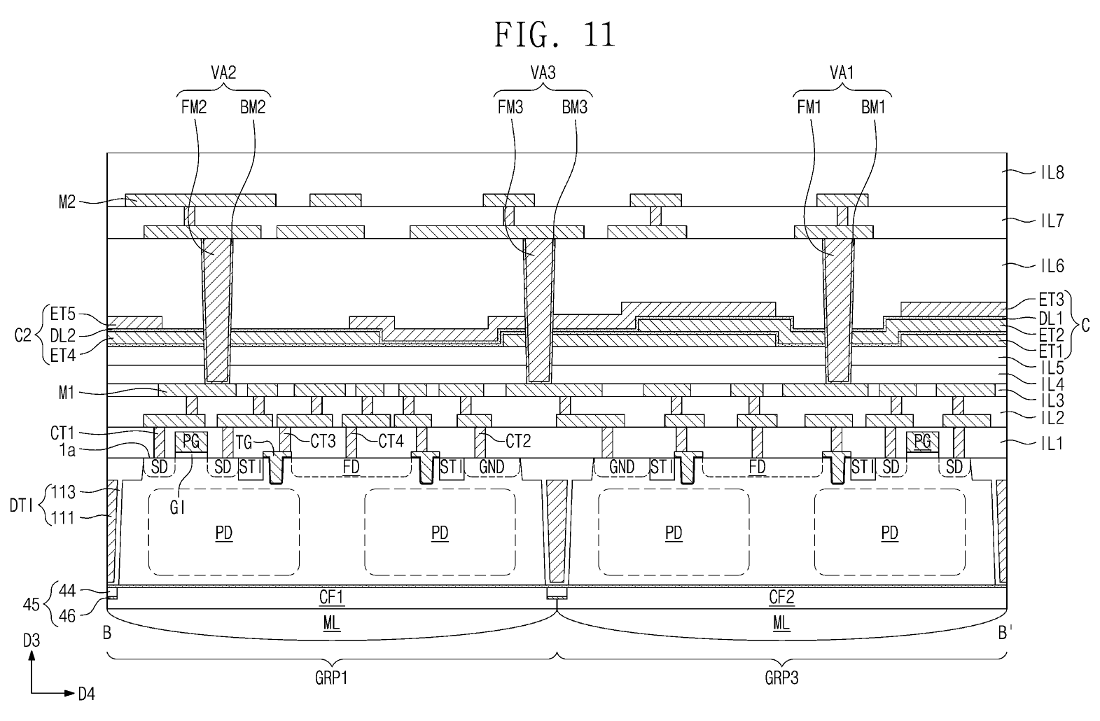

FIG. 10 is a plan view of an image sensor according to some embodiments of the present disclosure. FIG. 11 is a cross-sectional view taken along line B-B’ of FIG. 10 according to some embodiments of the present disclosure.

Referring to FIGS. 10 and 11, an image sensor IMS according to an embodiment of the present disclosure may include a first pixel group GRP1 to a fourth pixel group GRP4 arranged in a clockwise direction on a substrate 1. The first pixel group GRP1 and the second pixel group GRP2 may be adjacent to each other in the first direction D1. The second pixel group GRP2 and the third pixel group GRP3 may be adjacent to each other in the second direction D2. The third pixel group GRP3 and the fourth pixel group GRP4 may be adjacent to each other in the first direction D1. The first pixel group GRP1 and the fourth pixel group GRP4 may be adjacent to each other in the second direction D2. The first pixel group GRP1 to the fourth pixel group GRP4 may be separated by the isolation structure DTI.

Each of the first pixel group GRP1 to the fourth pixel group GRP4 may include a plurality of the light-receiving areas PX and the photodiode parts PD in the light-receiving areas PX. The first pixel group GRP1 to the fourth pixel group GRP4 and the photodiode parts PD therein may be separated from each other by the isolation structure DTI.

Each of the light-receiving areas PX may include a first active region ACT1 and a second active region ACT2 separated by the device isolation portion STI. Each of the plurality of the light-receiving regions PX may include a pixel transistor PG disposed within the first interlayer insulating layer ILD1 on a first active region ACT1. The ground region GND may be provided in each of the light-receiving areas PX. The arrangement of the pixel transistor PG and the ground region GND is not limited to that illustrated and may be combined and changed in various ways.

Each of the plurality of light-receiving regions PX may include a transfer transistor TG. A floating diffusion region FD may be provided in the substrate 1 and adjacent to the transfer transistor TG. When a voltage is applied to the transfer transistor TG, electrons may move to the floating diffusion region FD. Through the floating diffusion region FD, the plurality of light-receiving regions PX included in each of the pixel groups GRP1-GRP4 may be electrically connected to each other.

The transfer transistor TG may be provided on the first surface 1a of the substrate 1. For example, a portion of the transfer transistor TG may be provided in the substrate 1. The remaining portion of the transfer transistor TG may be provided on the first surface 1a. For example, a portion of the transfer transistor TG may extend into the substrate 1. A gate insulating layer may be interposed between the transfer transistor TG and the substrate 1.

According to some embodiments of the present disclosure, the isolation structure DTI may be provided on the floating diffusion region FD. In this case, the isolation structure DTI may be separated from the floating diffusion region FD.

Third contact plugs CT3 and fourth contact plugs CT4 may be provided to penetrate the first interlayer insulating layer IL1. The third contact plugs CT3 may be connected to a transfer transistor TG. The fourth contact plugs CT4 may be connected to the floating diffusion region FD.

The first capacitor C1 may, for example, overlap with at least a portion of the third pixel group GRP3 and at least a portion the fourth pixel group GRP4. The second capacitor C2 may, for example, overlap with at least a portion of the first pixel group GRP1 and at least a portion of the second pixel group GRP2. The structural features of the first capacitor C1, the second capacitor C2, and the first to third vias VA1-VA3 illustrated in FIG. 11 may correspond to those described in FIG. 5.

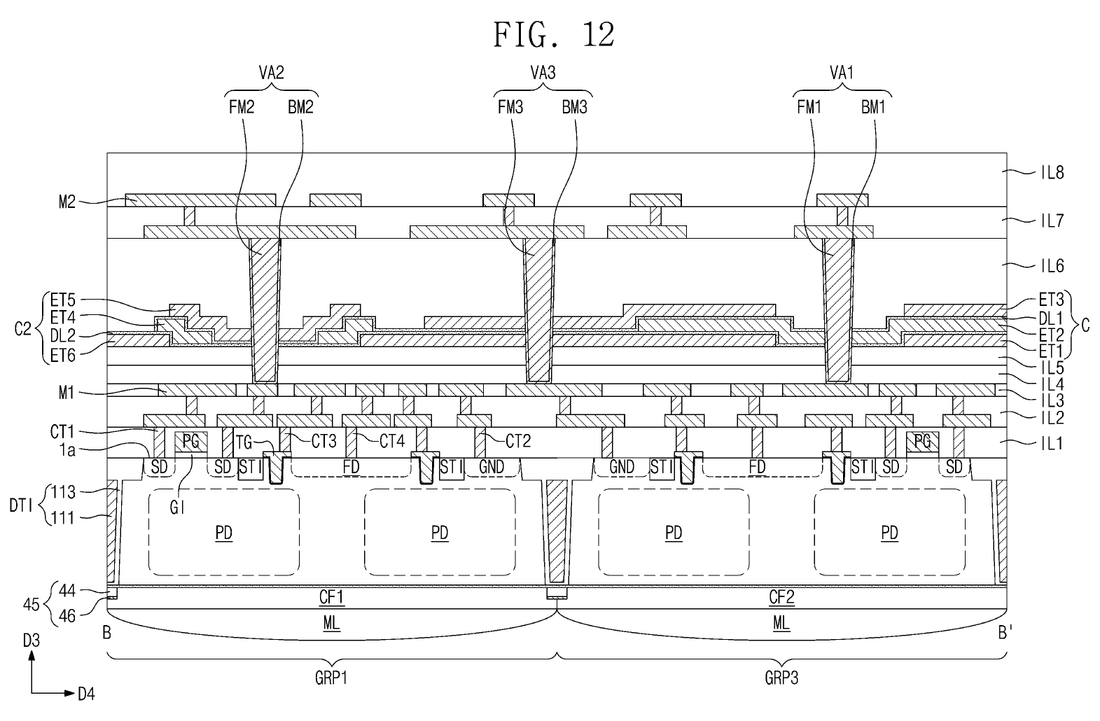

FIG. 12 is a cross-sectional view taken along line B-B’ of FIG. 10 according to some embodiments of the present disclosure.

Referring to FIGS. 10 and 12, the plates formed by the first electrode ET1 and the sixth electrode ET6 may be arranged on a plurality of pixel groups GRP1-GRP4. For example, the plate formed by the first electrode ET1 and the sixth electrode ET6 may be extended over a plurality of pixel groups GRP1-GRP4. The structural features of the first capacitor C1, the second capacitor C2, and the first to third vias VA1-VA3 illustrated in FIG. 12 may correspond to those described in FIG. 9.

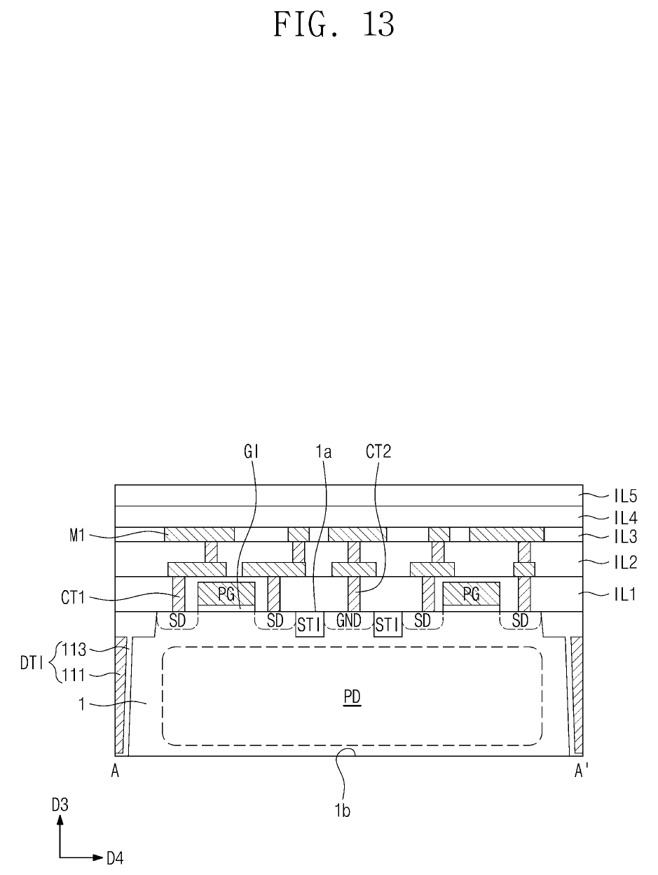

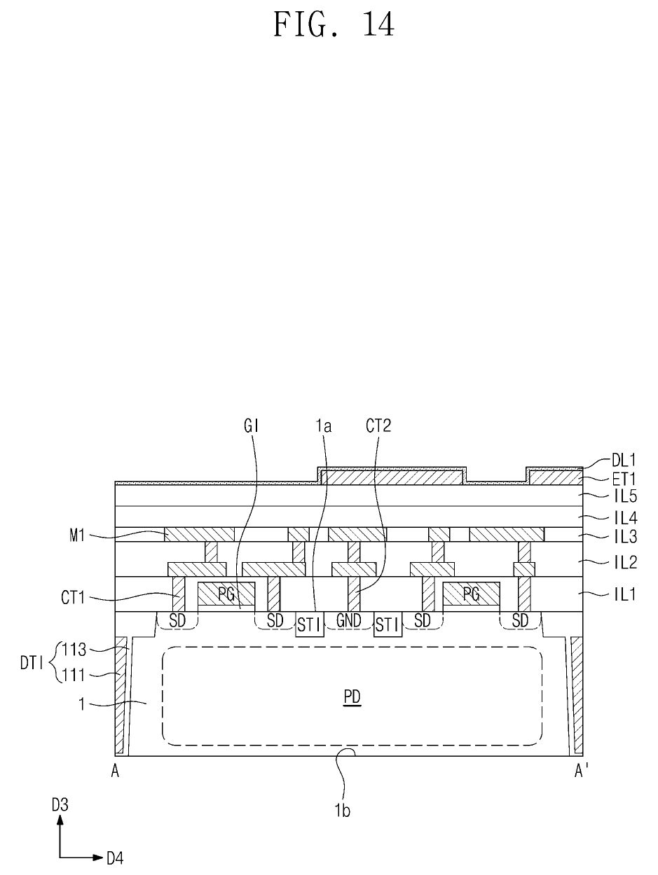

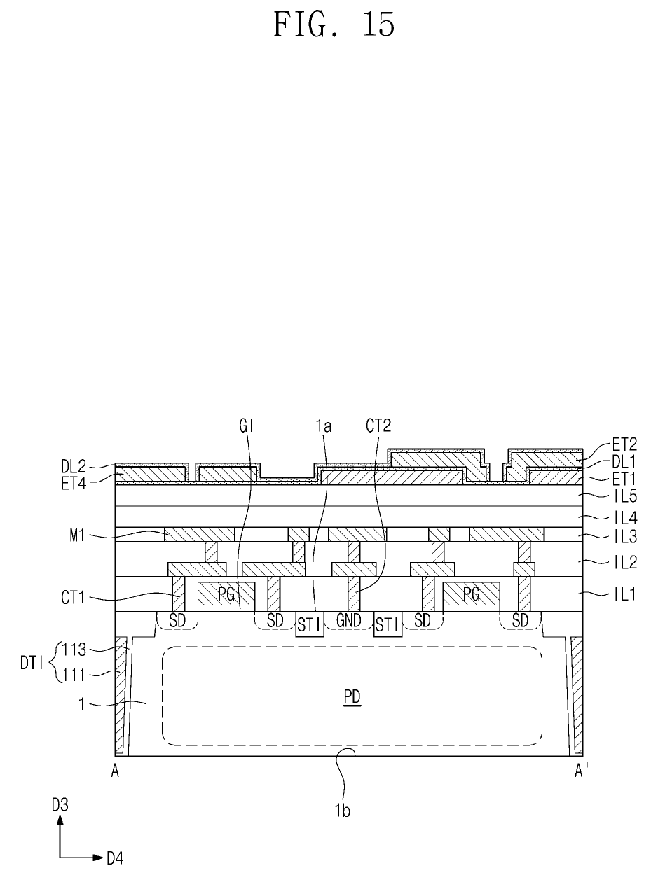

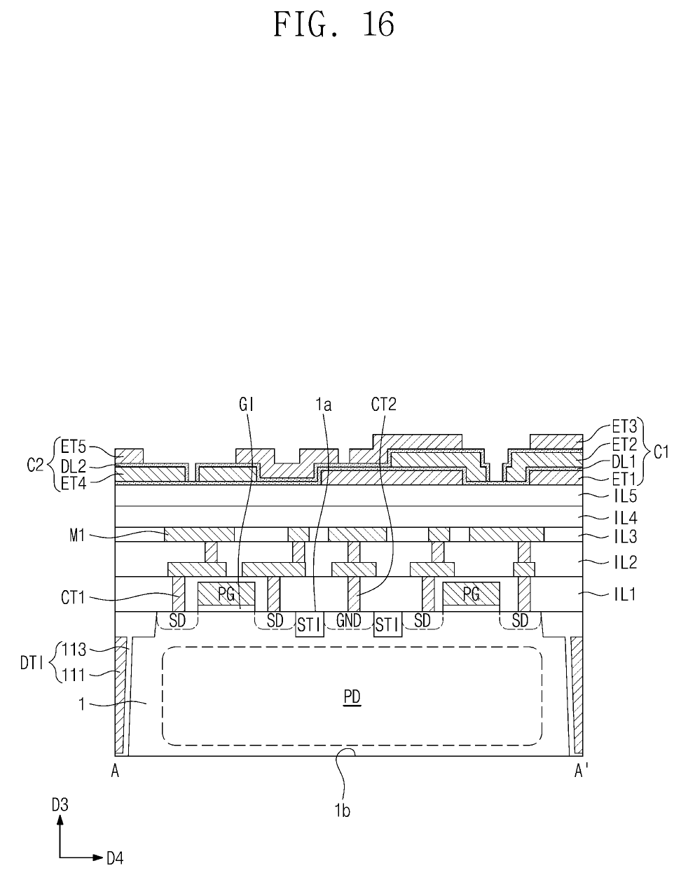

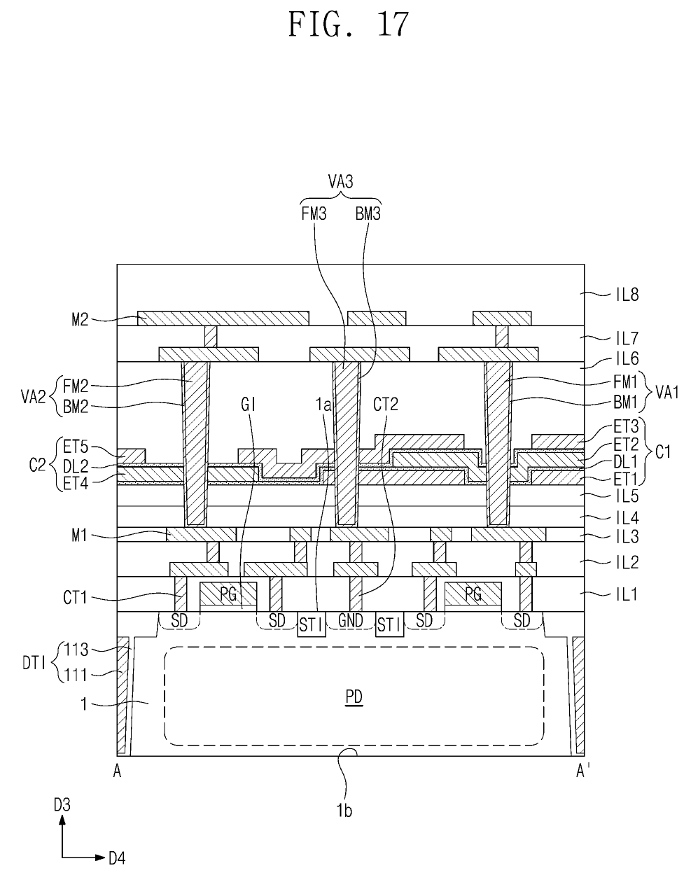

FIGS. 13, 14, 15, 16, and 17, are cross-sectional views illustrating a manufacturing process of an image sensor according to some embodiments of the present disclosure.

Referring to FIG. 13, a substrate 1 may be prepared. The substrate 1 may have a first surface 1a and a second surface 1b opposite to each other. A device isolation portion STI may be formed in the first surface 1a of the substrate 1. The device isolation portion STI may be formed, for example, through a shallow trench isolation process.

An isolation structure DTI may be formed by penetrating the device isolation portion STI and the substrate 1. The isolation structure DTI may include a first isolation pattern 111 and a second isolation pattern 113. A photodiode part PD may be formed in the substrate 1 through an ion implantation process. A ground region GND may be formed in the first surface 1a of the substrate 1.

A pixel transistor PG may be formed on the first surface 1a of the substrate 1. Within the substrate 1, source/drain regions SD may be formed through an ion implantation process.

A first interlayer insulating layer IL1 may be formed on the first surface 1a. A first contact plug CT1 and a second contact plug CT2 may be formed by penetrating the first interlayer insulating layer IL1. Thereafter, the second interlayer insulating layer to the fifth interlayer insulating layer IL2-IL5 and the first wiring patterns M1 provided therein may be formed.

Referring to FIG. 14, a first electrode ET1 may be formed on the fifth interlayer insulating layer IL5. Forming the first electrode ET1 may include forming an electrode layer on the fifth interlayer insulating layer IL5 and performing a patterning process on the electrode layer. Due to the patterning process, the first electrode ET1 may have an opening. The first electrode ET1 may be formed, for example, through a chemical vapor deposition process.

Thereafter, a first dielectric layer DL1 covering the upper surface of the fifth interlayer insulating layer IL5 and the upper surface and side surface of the first electrode ET1 may be formed. The first dielectric layer DL1 may be formed, for example, through an atomic layer deposition process.

Referring to FIG. 15, a second electrode ET2 may be formed on a first electrode ET1. A fourth electrode ET4 may be formed on the first dielectric layer DL1. The second electrode ET2 may have a step structure.

Forming the second electrode ET2 may include forming an electrode layer on the first electrode ET1 and performing a patterning process on the electrode layer. The second electrode ET2 may fill a part of the opening formed in FIG. 14.

Forming the fourth electrode ET4 may include forming an electrode layer on the first dielectric layer DL1 and performing a patterning process on the electrode layer. According to the patterning process, the fourth electrode ET4 may have an opening.

For example, forming the second electrode ET2 and the fourth electrode ET4 may be performed simultaneously. The second electrode ET2 and the fourth electrode ET4 may be formed, for example, through a chemical vapor deposition process.

Thereafter, a first dielectric layer DL1 covering the second electrode ET2 and a second dielectric layer DL2 covering the fourth electrode ET4 may be formed. The second dielectric layer DL2 may be formed, for example, through an atomic layer deposition process.

Referring to FIG. 16, a third electrode ET3 may be formed on a second electrode ET2. A fifth electrode ET5 may be formed on the fourth electrode ET4. The third electrode ET3 and the fifth electrode ET5 may have a step structure.

Forming the third electrode ET3 may include forming an electrode layer on the second electrode ET2 and performing a patterning process on the electrode layer. The third electrode ET3 may not fill the opening formed in FIG. 14.

Forming the fifth electrode ET5 may include forming an electrode layer on the fourth electrode ET4 and performing a patterning process on the electrode layer.

For example, forming the third electrode ET3 and the fifth electrode ET5 may be performed simultaneously. The third electrode ET3 and the fifth electrode ET5 may be formed, for example, through a chemical vapor deposition process.

As the third electrode ET3 is formed, a first capacitor C1 including a first electrode ET1, a second electrode ET2, a third electrode ET3, and a first dielectric layer DL1 may be formed. As the fifth electrode ET5 is formed, a second capacitor C2 including the fourth electrode ET4, the fifth electrode ET5 and the second dielectric layer DL2 may be formed.

Referring to FIG. 17, a sixth interlayer insulating layer IL6 covering the first capacitor C1 and the second capacitor C2 may be formed. Thereafter, a first via VA1, a second via VA2, and a third via VA3 penetrating the fourth interlayer insulating layer IL4 to the sixth interlayer insulating layer IL6 may be formed.

The first via VA1 may be connected to the second electrode ET2 of the first capacitor C1. The second via VA2 may be connected to the fourth electrode ET4 of the second capacitor C2. The third via VA3 may be connected to the first electrode ET1, the third electrode ET3 of the first capacitor C1 and the fifth electrode ET5 of the second capacitor C2.

The first via VA1 may include a first conductive pattern FM1 and a first barrier pattern BM1 on the first conductive pattern FM1. The second via VA2 may include a second conductive pattern FM2 and a second barrier pattern BM2 on the second conductive pattern FM2. The third via VA3 may include a third conductive pattern FM3 and a third barrier pattern BM3 on the third conductive pattern FM3.

A seventh interlayer insulating layer IL7, an eighth interlayer insulating layer IL8, and second wiring patterns M2 arranged therein may be formed on a sixth interlayer insulating layer IL6. In one or more examples, some of the second wiring patterns M2 may be connected to the first to third vias VA1-VA3.

Thereafter, referring to FIG. 5, an image sensor according to some embodiments of the present disclosure may be completed by forming a fixed charge layer 42, a color filter CF, and a micro lens ML on the second surface 1b of the substrate 1.

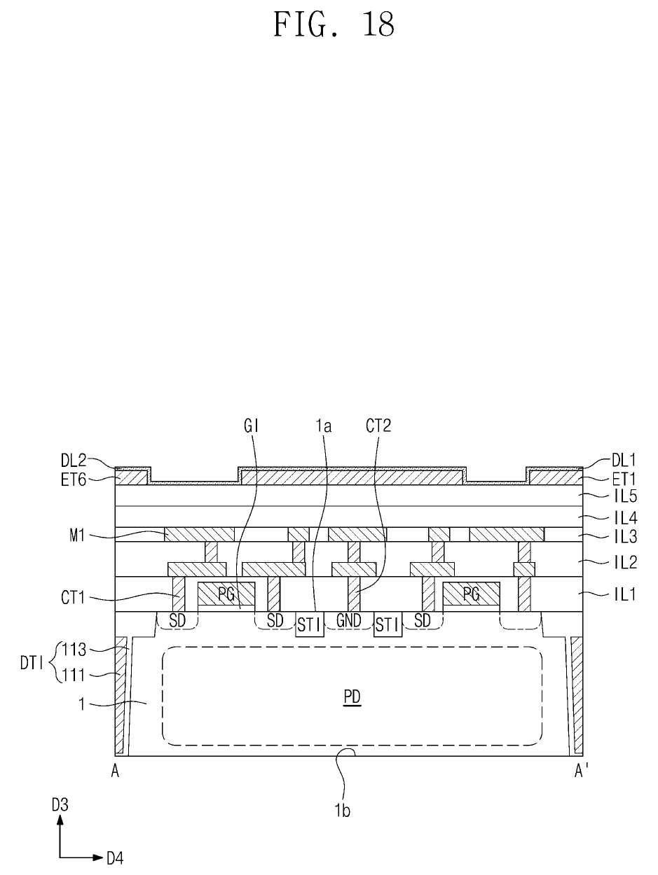

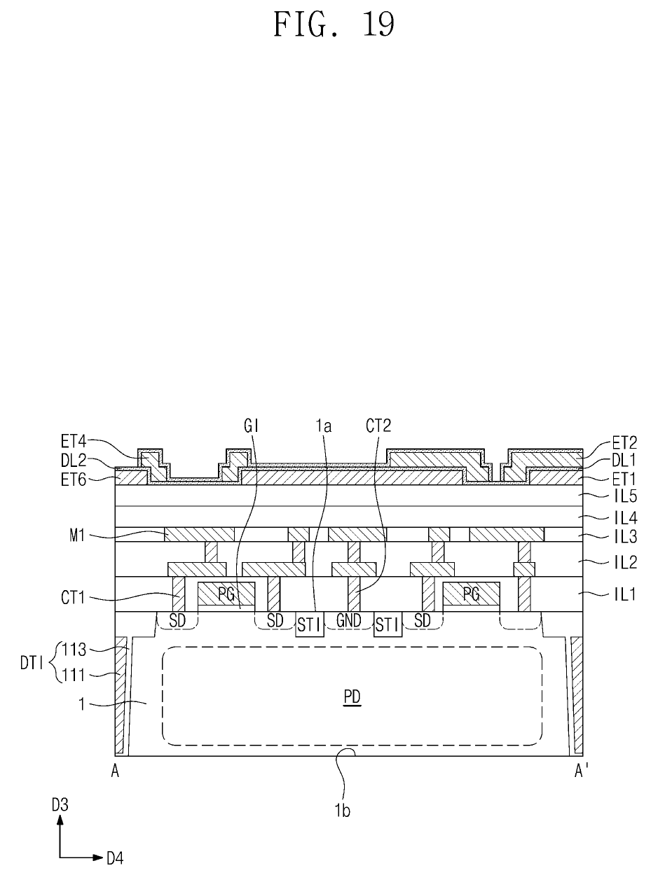

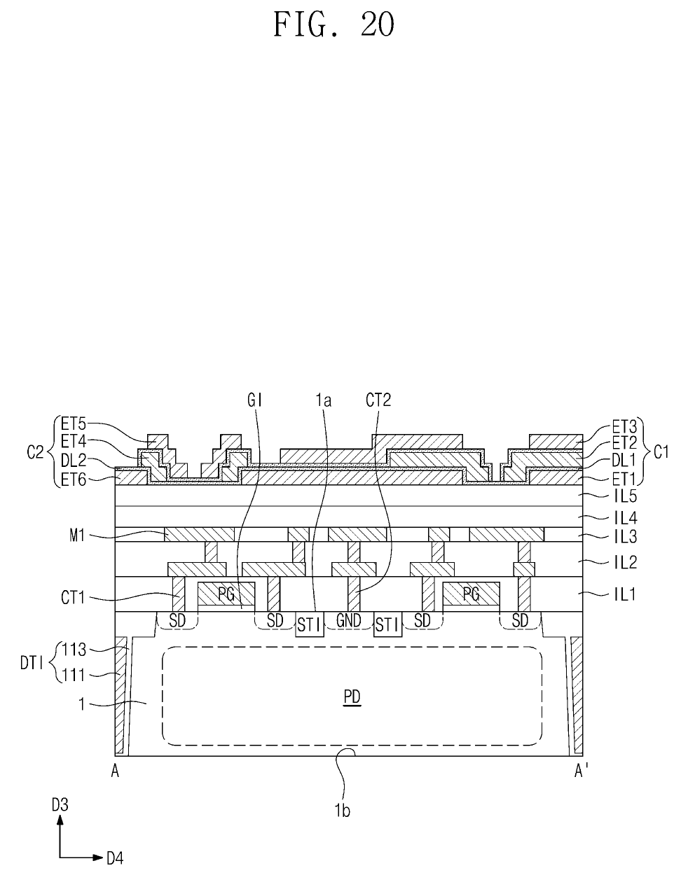

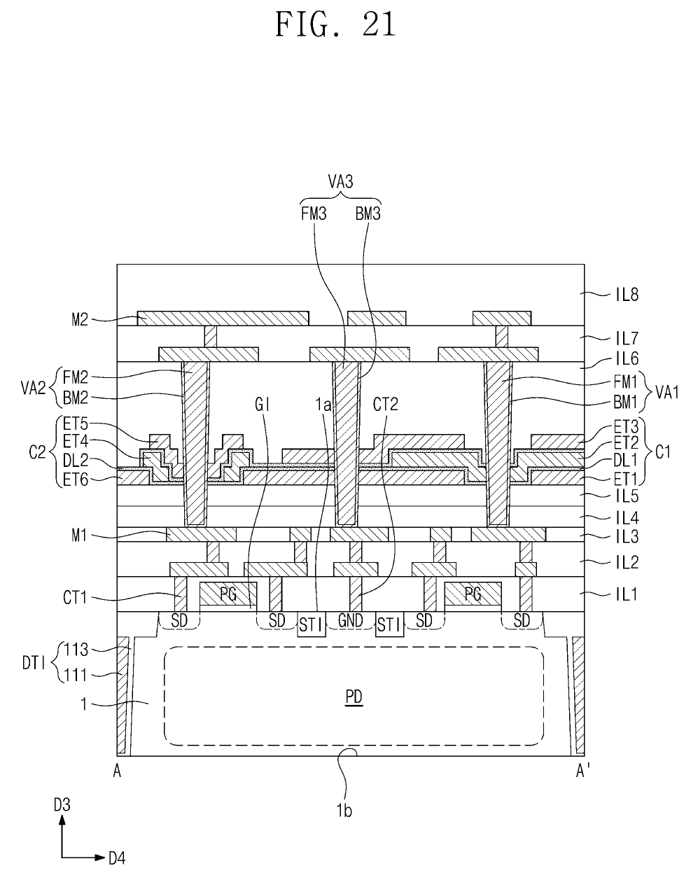

FIGS. 18, 19, 20, and 21 are cross-sectional views illustrating a manufacturing process of an image sensor according to some embodiments of the present disclosure.

Referring to FIG. 13 and FIG. 18, a first electrode ET1 and a sixth electrode ET6 may be formed on a fifth interlayer insulating layer IL5.

Forming the first electrode ET1 may include forming an electrode layer on the fifth interlayer insulating layer IL5 and performing a patterning process on the electrode layer. Due to the patterning process, the first electrode ET1 may have an opening.

Forming the sixth electrode ET6 may include forming an electrode layer on the fifth interlayer insulating layer IL5 and performing a patterning process on the electrode layer. According to the patterning process, the sixth electrode ET6 may have an opening.

The first electrode ET1 and sixth electrode ET6 may be formed, for example, through a chemical vapor deposition process. In one or more examples, the first electrode ET1 and the sixth electrode ET6 may form a single plate. For example, forming the first electrode ET1 and the sixth electrode ET6 may be performed simultaneously.

Thereafter, a first dielectric layer DL1 covering the upper surface of the fifth interlayer insulating layer IL5, the upper surface and side surface of the first electrode ET1, and the upper surface and side surface of the sixth electrode ET6 may be formed. The first dielectric layer DL1 may be formed, for example, through an atomic layer deposition process.

Referring to FIG. 19, a second electrode ET2 may be formed on a first electrode ET1. A fourth electrode ET4 may be formed on the sixth electrode ET6. The second electrode ET2 and the fourth electrode ET4 may have a step structure.

Forming the second electrode ET2 may include forming an electrode layer on the first electrode ET1 and performing a patterning process on the electrode layer. The second electrode ET2 may fill part of the opening of the first electrode ET1 formed in FIG. 18.

Forming the fourth electrode ET4 may include forming an electrode layer on the sixth electrode ET6 and performing a patterning process on the electrode layer. The fourth electrode ET4 may fill part of the opening of the sixth electrode ET6 formed in FIG. 18.

For example, forming the second electrode ET2 and the fourth electrode ET4 may be performed simultaneously. The second electrode ET2 and the fourth electrode ET4 may be formed, for example, through a chemical vapor deposition process.

Thereafter, a first dielectric layer DL1 covering the second electrode ET2 and a second dielectric layer DL2 covering the fourth electrode ET4 may be formed. The second dielectric layer DL2 may be formed, for example, through an atomic layer deposition process.

Referring to FIG. 20, a third electrode ET3 may be formed on a second electrode ET2. A fifth electrode ET5 may be formed on the fourth electrode ET4. The third electrode ET3 and the fifth electrode ET5 may have a step structure.

Forming the third electrode ET3 may include forming an electrode layer on the second electrode ET2 and performing a patterning process on the electrode layer. The third electrode ET3 may not fill the opening of the first electrode ET1 formed in FIG. 18.

Forming the fifth electrode ET5 may include forming an electrode layer on the fourth electrode ET4 and performing a patterning process on the electrode layer. The fifth electrode ET5 may fill part of the opening of the sixth electrode ET6 formed in FIG. 18.

For example, forming the third electrode ET3 and the fifth electrode ET5 may be performed simultaneously. The third electrode ET3 and the fifth electrode ET5 may be formed, for example, through a chemical vapor deposition process.

As the third electrode ET3 is formed, a first capacitor C1 including a first electrode ET1, a second electrode ET2, a third electrode ET3, and a first dielectric layer DL1 may be formed. As the fifth electrode ET5 is formed, a second capacitor C2 including the fourth electrode ET4, the fifth electrode ET5 and the second dielectric layer DL2 may be formed.

Referring to FIG. 21, a sixth interlayer insulating layer IL6 covering the first capacitor C1 and the second capacitor C2 may be formed. Thereafter, a first via VA1, a second via VA2, and a third via VA3 penetrating the fourth interlayer insulating layer IL4 to the sixth interlayer insulating layer IL6 may be formed. The first via VA1 may be connected to the second electrode ET2 of the first capacitor C1. The second via VA2 may be connected to the fifth electrode ET5 of the second capacitor C2. The third via VA3 may be connected to the first electrode ET1, the third electrode ET3 of the first capacitor C1 and the sixth electrode ET6 of the second capacitor C2.

The first via VA1 may include a first conductive pattern FM1 and a first barrier pattern BM1 on the first conductive pattern FM1. The second via VA2 may include a second conductive pattern FM2 and a second barrier pattern BM2 on the second conductive pattern FM2. The third via VA3 may include a third conductive pattern FM3 and a third barrier pattern BM3 on the third conductive pattern FM3.

A seventh interlayer insulating layer IL7, an eighth interlayer insulating layer IL8, and second wiring patterns M2 provided therein may be formed on a sixth interlayer insulating layer IL6. In one or more examples, some of the second wiring patterns M2 may be connected to the first to third vias VA1-VA3.

Thereafter, referring to FIG. 5, an image sensor according to some embodiments of the present disclosure may be completed by forming a fixed charge layer 42, a color filter CF, and a micro lens ML on the second surface 1b of the substrate 1.

An image sensor according to an embodiment of the present disclosure may include a first capacitor and a second capacitor provided on a substrate including a photodiode part. In one or more examples, a number of electrodes of the second capacitor may be less than or equal to a number of electrodes of the first capacitor, or the electrical connection form between the electrodes included in each capacitor may be different, such as parallel or series. Due to this, the capacitance value of the first capacitor may be greater than that of the second capacitor. As a result, the plurality of capacitors having different capacitance values may be advantageously provided and arranged in the image sensor according to the required capacitance value, thereby resulting in improved electrical characteristics of the image sensor.

While embodiments are described above, a person skilled in the art may understand that many modifications and variations are made without departing from the spirit and scope of the present disclosure defined in the following claims. Accordingly, the example embodiments of the present disclosure should be considered in all respects as illustrative and not restrictive, with the spirit and scope of the present disclosure being indicated by the appended claims.

What is claimed is:

1. An image sensor, comprising:
a substrate comprising a first pixel having a first photodiode and a second pixel having a second photodiode; and
a first capacitor and a second capacitor spaced apart from each other in a first direction,
wherein the first capacitor comprises N electrodes and M dielectric layers including a first dielectric layer,
wherein the second capacitor comprises L electrodes and T dielectric layers including a second dielectric layer,
wherein the first dielectric layer is disposed between two electrodes included in N electrodes,
wherein the second dielectric layer is disposed between two electrodes included in L electrodes,
wherein at least a portion of the first capacitor is overlapped with the first photodiode in a second direction perpendicular to the first direction,
wherein N and L are integer equal or greater than 2,
wherein M and T are integer equal or greater than 1,
wherein N is different from L, and
wherein each of N electrodes are sequentially stacked in the second direction.

2. The image sensor of claim 1, further comprises a first isolation structure in the substrate and a second isolation structure in the substrate,
wherein the first photodiode is disposed between the first isolation structure and the second isolation structure, and
wherein the first capacitor is overlapped with the first isolation structure in the second direction.

3. The image sensor of claim 1, further comprises a first via connected to the first capacitor penetrating at least one electrode of N electrodes.

4. The image sensor of claim 3, further comprises a second via connected to the second capacitor penetrating at least one electrode of L electrodes.

5. The image sensor of claim 3, wherein the first capacitor is shared by the first and second pixels.

6. The image sensor of claim 5, wherein the first and second capacitors are shared by the first and second pixels.

7. The image sensor of claim 1, wherein N electrodes comprise a first electrode and L electrodes comprise a second electrode,
wherein an area of the first electrode in a plan view is different from an area of the second electrode in the plan view.

8. The image sensor of claim 7, wherein a difference between N and L is equal or greater than 1.

9. The image sensor of claim 6, wherein the substrate further comprises a third pixel and the fourth pixel,
wherein the first to fourth pixels are arranged in a 2x2 matrix form in the plan view, and
wherein the first and second capacitors are shared by the first to fourth pixels.

10. The image sensor of claim 5, wherein at least a portion of the second capacitor is overlapped with the second photodiode in the second direction perpendicular to the first direction.

11. The image sensor of claim 1, wherein a difference between N and L is equal or greater than 2.

12. An image sensor, comprising:
a substrate comprising a first photodiode and a second photodiode;
a first capacitor and a second capacitor spaced apart from each other in a first direction; and
S interlayer insulating layers between the substrate and the first capacitor,
wherein the first capacitor comprises N electrodes and M dielectric layers including a first dielectric layer,
wherein the second capacitor comprises L electrodes and T dielectric layers including a second dielectric layer,
wherein the first dielectric layer is disposed between two electrodes included in N electrodes,
wherein the second dielectric layer is disposed between two electrodes included in L electrodes,
wherein at least a portion of the first capacitor is overlapped with the first photodiode in a second direction perpendicular to the first direction,
wherein S, N and L are integer equal or greater than 2,
wherein M and T are integer equal or greater than 1,
wherein N is different from L, and
wherein L is smaller than N.

13. The image sensor of claim 12, wherein S is equal or greater than 3.

14. The image sensor of claim 13, wherein each of N electrodes are sequentially stacked in the second direction.

15. The image sensor of claim 14, wherein the first photodiode is included in a first pixel and the second photodiode is included in a second pixel, and
wherein the first and second capacitors are shared by the first and second pixels.

16. The image sensor of claim 15, wherein a difference between N and L is equal or greater than 1.

17. The image sensor of claim 15, wherein a difference between N and L is equal or greater than 2.

18. The image sensor of claim 15, further comprises a first isolation structure in the substrate and a second isolation structure in the substrate,
wherein the first photodiode is disposed between the first isolation structure and the second isolation structure, and
wherein the first capacitor is overlapped with the first isolation structure in the second direction.

19. The image sensor of claim 16, further comprises a wiring pattern between the substrate and the first capacitor, and
wherein S is equal or greater than 4.

20. An image sensor, comprising:
a substrate comprising a first photodiode and a second photodiode;
a first capacitor and a second capacitor spaced apart from each other in a first direction; and
S interlayer insulating layers between the substrate and the first capacitor,
wherein the first capacitor comprises N electrodes and M dielectric layers including a first dielectric layer,
wherein the second capacitor comprises L electrodes and T dielectric layers including a second dielectric layer,
wherein the first dielectric layer is disposed between two electrodes included in N electrodes,
wherein the second dielectric layer is disposed between two electrodes included in L electrodes,
wherein at least a portion of the first capacitor is overlapped with the first photodiode in a second direction perpendicular to the first direction,
wherein S, N and L are integer equal or greater than 2,
wherein M and T are integer equal or greater than 1,
wherein N is different from L,
wherein each of N electrodes are sequentially stacked in the second direction, and
wherein electrons generated by the first and photodiode and second photodiodes are stored at the first capacitors.
